(19) United States
(12) Patent Application Publication
(10) Pub. No.: US 2022/0369469 A1
(43) Pub. Date: Nov. 17, 2022

(54) METHOD OF MANUFACTURING PRINTED WIRING BOARD

(71) Applicant: TANAZAWA HAKKOSHA CO., LTD., Higashiosaka-shi, Osaka (JP)

(72) Inventors: Keiichiro YAMAMOTO, Higashiosaka-shi, Osaka (JP); Kazuo TANI, Higashiosaka-shi, Osaka (JP); Masaharu YANO, Higashiosaka-shi, Osaka (JP)

(73) Assignee: TANAZAWA HAKKOSHA CO., LTD., Higashiosaka-shi, Osaka (JP)

(21) Appl. No.: 17/424,536

(22) PCT Filed: Jan. 21, 2020
(86) PCT No.: PCT/JP2020/001885

§ 371 Date: Jul. 21, 2021

(30) Foreign Application Priority Data
Feb. 6, 2019 (JP) 2019-019375

(51) Int. Cl. H05K 3/06; H05K 3/40

(52) U.S. Cl. CPC H05K 3/064; H05K 3/4007; H05K 2203/161; H05K 2203/0588

(57) ABSTRACT

In a method of manufacturing a printed wiring board with a pattern formed using a printing process, a pattern of a portion requiring position accuracy can be accurately formed at a predetermined position.

A method of manufacturing a printed wiring board 10 according to the present invention includes preparing a laminated board 12 including a metal layer 16 formed on a surface of a base material 14, forming a first etching resist layer 20a by printing a pattern of a portion 18a requiring position accuracy on the metal layer of the laminated board using a metal mask 32, forming a second etching resist layer 20b by printing a pattern of a portion 18b other than the portion requiring position accuracy on the metal layer of the laminated board using a screen plate 34, removing, by etching, the metal layer of the laminated board where the first etching resist layer and the second etching resist layer are not formed, and stripping the first etching resist layer and the second etching resist layer.

### TECHNICAL FIELD

The present invention relates to a method of manufacturing a printed wiring board, and more particularly relates to a method of manufacturing a printed wiring board in which a pattern is formed by a printing process.

### BACKGROUND ART

Conventional methods of manufacturing a printed wiring board include a method of forming a pattern by a subtractive process using a laminated board in which a metal layer is formed on a surface of a base material formed of an insulator. In this method, a printing process is used in which a pattern is printed using a screen plate and a part of the metal layer other than the pattern is removed by etching (see, for example, PTL 1).

A method of manufacturing a printed wiring board by a printing process according to the prior art will be described below with reference to the flowchart of FIG. 11.

First, a laminated board in which a metal layer is formed on a surface of a base material formed of an insulator is prepared (step S101).

Next, after pretreatment processes such as cleaning and roughness formation, printing with an etching resist ink is performed on a pattern portion of the metal layer of the laminated board by using a screen plate (step S102).

Subsequently, the etching resist ink is cured to form an etching resist layer (step S103).

Next, the metal layer of the laminated board is etched to remove an unnecessary portion (a portion other than the pattern) (step S104).

Subsequently, the etching resist layer is stripped to remove the etching resist layer of the pattern (step S105).

Next, a solder resist layer is formed by performing, on a portion of the pattern not to be soldered, solder resist printing using a solder resist ink, and then, curing the solder resist ink (step S106).

Finally, a process for forming an outer shape and holes (step S107), and a process for finishing the surface (step S108) are performed. In the process of finishing the surface, acid is used to degrease and rust-proof the surface, with the purpose of cleaning the portion of the pattern where the solder resist layer is not formed. As a result, the printed wiring board in which the pattern is formed on the base material is manufactured.

Such a method of manufacturing a printed wiring board by a printing process in which a pattern is formed by using a screen plate is widely employed, because it is highly suitable for mass production and allows for production at low cost.

### CITATION LIST

### Patent Literature

PTL 1: WO 2016/157552

### SUMMARY OF INVENTION

### Technical Problem

In recent years, with the progress of miniaturization and increase in density of electronic components, it is required to form a pattern of a printed wiring board with higher accuracy.

However, in a conventional printing process using a screen plate, printing with the etching resist ink is performed while pulling the screen plate, and thus a positional deviation often occurs in the etching resist layer. Therefore, there is a problem in that it is difficult to accurately form a pattern at a predetermined position. In particular, when a positional deviation in a land portion for mounting an electronic component is large, there is a problem in that a malfunction such as a short circuit may occur. Further, in addition to the printing process, examples of the subtractive process include a photographic method and the like, but this method has the problem that the productivity is generally low and the cost is high.

Therefore, a main object of the present invention is to provide, in a method of manufacturing a printed wiring board in which a pattern is formed by a printing process, a method of manufacturing a printed wiring board capable of accurately forming, at a predetermined position, a pattern of a portion requiring position accuracy.

### Solution to Problem

A method of manufacturing a printed wiring board according to the present invention includes preparing a laminated board including a metal layer formed on a surface of a base material, forming a first etching resist layer by printing a pattern of a portion requiring position accuracy on the metal layer of the laminated board using a metal mask, forming a second etching resist layer by printing a pattern of a portion other than the portion requiring position accuracy on the metal layer of the laminated board using a screen plate, removing, by etching, the metal layer of the laminated board where the first etching resist layer and the second etching resist layer are not formed, and stripping the first etching resist layer and the second etching resist layer.

In the method of manufacturing a printed wiring board according to the present invention, the first etching resist layer is formed by printing a pattern of a portion requiring position accuracy using a metal mask, and thus, the pattern can be formed at a predetermined position with high accuracy, and it is possible to reduce malfunctions from a short circuit or the like. Further, the second etching resist layer is formed by printing a pattern of a portion other than the portion requiring position accuracy using a screen plate. Subsequently, portions where the first etching resist layer and the second etching resist layer are not formed are simultaneously removed by etching, and the first etching resist layer and the second etching resist layer are simultaneously stripped. Thus, it is possible to manufacture printed wiring boards in a process excellent in terms of overall mass productivity and cost reduction.

Here, the portion requiring position accuracy preferably includes a land portion for mounting an electronic component.

Further, the portion requiring position accuracy preferably includes a fiducial mark portion for positioning the printed wiring board.

High position accuracy is often required for the land portion for mounting the electronic component and the fiducial mark portion for positioning the printed wiring board, whereas other portions of the wiring pattern often do not require high position accuracy.

The thickness of the metal mask is preferably 0.02 mm or more. When a metal mask having a thickness of 0.02 mm or more is chosen, it is possible to prevent the metal mask from being deformed due to the printing pressure of a squeegee or the like.

The metal mask is preferably a combination mask.

When a combination mask is used as the metal mask, the cost can be reduced, compared to a case where a directly attached metal mask produced by using a metal plate alone is used.

In the forming the first etching resist layer and the forming the second etching resist layer, it is preferable to print the pattern by using a UV-curable ink.

When the UV-curable ink is used to print the pattern when forming the first etching resist layer and the second etching resist layer, the first etching resist layer and the second etching resist layer can be formed at a low temperature, and it is possible to appropriately form the first etching resist layer and the second etching resist layer in a state where the base material contracts little.

When printing the pattern by using the metal mask in the forming the first etching resist layer, it is preferable to use a squeegee having a type A durometer hardness defined in JIS K6253-3 of 60 or more.

When the squeegee having a hardness of 60 or more is used in printing the pattern by using the metal mask in forming the first etching resist layer, it is possible to smoothly print the pattern.

### Advantageous Effects of Invention

According to the present invention, it is possible to provide a method of manufacturing a printed wiring board that allows for accurately forming, at a predetermined position, a pattern of a portion requiring position accuracy, improving overall mass productivity, and achieving cost reduction.

The above-mentioned object, other objects, features, and advantages of the present invention will become more obvious from the description of the embodiments for carrying out the invention, described below with reference to the drawings.

### BRIEF DESCRIPTION OF DRAWINGS

FIG. 1 is a diagram illustrating a schematic structure of a printed wiring board according to an example, formed by a method of manufacturing a printed wiring board according to an embodiment of the present invention.

FIG. 2 is a flowchart for describing a method of manufacturing a printed wiring board according to the embodiment of the present invention.

FIG. 3 is a cross-sectional view of a printed wiring board for describing step S001 of the method of manufacturing the printed wiring board according to the embodiment of the present invention.

FIG. 4 is a cross-sectional view of the printed wiring board for describing step S002 of the method of manufacturing the printed wiring board according to the embodiment of the present invention.

FIG. 5 is a cross-sectional view of the printed wiring board for describing step S003 of the method of manufacturing the printed wiring board according to the embodiment of the present invention.

FIG. 6 is a cross-sectional view of the printed wiring board for describing step S004 of the method of manufacturing the printed wiring board according to the embodiment of the present invention.

FIG. 7 is a cross-sectional view of the printed wiring board for describing step S005 of the method of manufacturing the printed wiring board according to the embodiment of the present invention.

FIG. 8 is a cross-sectional view of the printed wiring board for describing step S006 of the method of manufacturing the printed wiring board according to the embodiment of the present invention.

FIG. 9 is a cross-sectional view of the printed wiring board for describing step S007 of the method of manufacturing the printed wiring board according to the embodiment of the present invention.

FIGS. 10A to 10D are plan views for describing the method of manufacturing the printed wiring board according to the embodiment of the present invention.

FIG. 11 is a flowchart illustrating a conventional method of manufacturing a printed wiring board.

FIG. 12 is a diagram illustrating printing accuracy in step S002 of the method of manufacturing the printed wiring board according to the embodiment of the present invention.

FIG. 13 is a diagram illustrating printing accuracy in step S102 of the conventional method of manufacturing a printed wiring board.

FIGS. 14A and 14B are diagrams illustrating a schematic structure in which electronic components are mounted on the printed wiring board according to an example formed by the method of manufacturing a printed wiring board according to the embodiment of the present invention.

### DESCRIPTION OF EMBODIMENTS

An embodiment of the present invention will be described below with reference to the accompanying drawings.

### 1. Printed Wiring Board

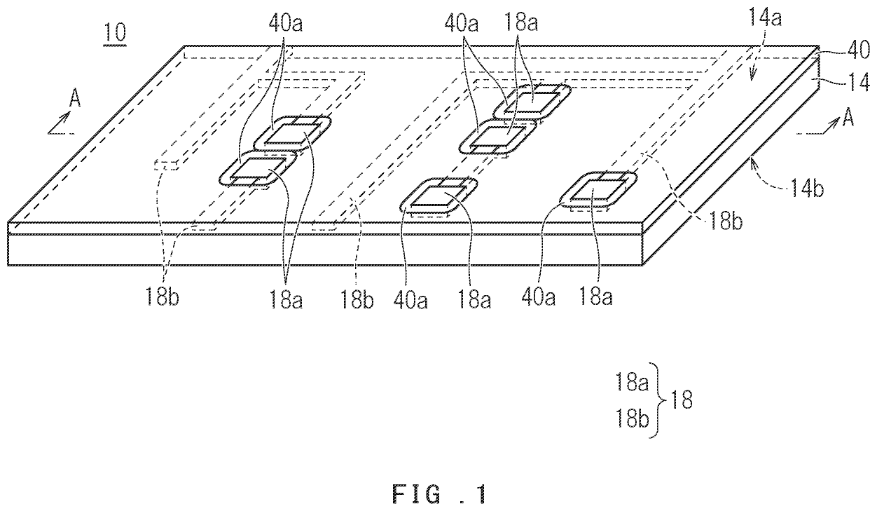

FIG. 1 is a diagram illustrating a schematic structure of a printed wiring board according to an example, formed by a method of manufacturing a printed wiring board according to the embodiment of the present invention. A schematic structure of a printed wiring board 10 according to an example of the present invention will be described below with reference to FIG. 1.

The printed wiring board 10 includes a base material 14. A pattern 18 is formed on a front surface 14a, being one surface of the base material 14. Note that the pattern 18 may be formed on a back surface 14b, being the other surface of the base material 14, or on both surfaces of the base material 14. If the pattern 18 is formed on both surfaces of the base material 14, a through hole penetrating the base material 14 may be formed in the base material 14 to electrically connect a pattern on the front surface 14a of the base material 14 and a pattern on the back surface 14b of the base material 14.

The base material 14 is formed of, for example, an insulating resin material having a thickness of 0.1 mm or more and 2.0 mm or less. The base material 14 is formed of, for example, a glass cloth epoxy resin laminated board, a phenolic paper substrate, an epoxy paper substrate, a glass composite substrate, a Teflon (registered trademark) substrate, an alumina substrate, a polyimide substrate, and the like.

The pattern 18 is formed of, for example, a metal such as Cu, Au, Pd, and Pt, or an alloy of these metals. The thickness of the pattern 18 is 18 μm or more and 70 μm or less. The pattern 18 is formed by etching a metal layer 16 provided on the front surface of the base material 14. The pattern 18 includes land portions 18a for mounting an electronic component 50 and wiring pattern portions 18b other than the land portions 18a.

The land portion 18a has two main surfaces and at least one side surface, and one of the two main surfaces (a first main surface) is in surface contact with the front surface 14a of the base material 14. Further, the electronic component 50 is mounted on the other main surface (a second main surface), for example. When the electronic component 50 is mounted, each of the land portions 18a and an adjacent one of the land portions 18a and a part of an external electrode of the electronic component 50 are electrically connected via a bonding material 52 such as solder. For example, when the size of the electronic component 50 in the longitudinal direction is 1.0 mm, the distance between the center of the land portion 18a and the center of the adjacent land portion 18a should be 0.5 mm or more and 1.5 mm or less. Therefore, the land portions 18a need to be accurately formed at predetermined positions. Consequently, the land portions 18a are portions requiring position accuracy.

The wiring pattern portion 18b other than the land portion has two main surfaces and at least one side surface, and one of the two main surfaces (a first main surface) is in surface contact with the front surface 14a of the base material 14. The wiring pattern portion 18b other than the land portion is mainly a portion that electrically connects the land portion 18a and the land portion 18a adjacent at a predetermined interval. Further, a part of the wiring pattern portion 18b other than the land portion is covered with a solder resist layer 40 in order to prevent solder adhesion to a portion that should not be soldered, protect the pattern, and maintain insulation reliability. Therefore, the wiring pattern portion 18b does not necessarily have to be formed at a predetermined position with high accuracy. Consequently, the wiring pattern portion 18b other than the land portion is a portion where position accuracy is not required.

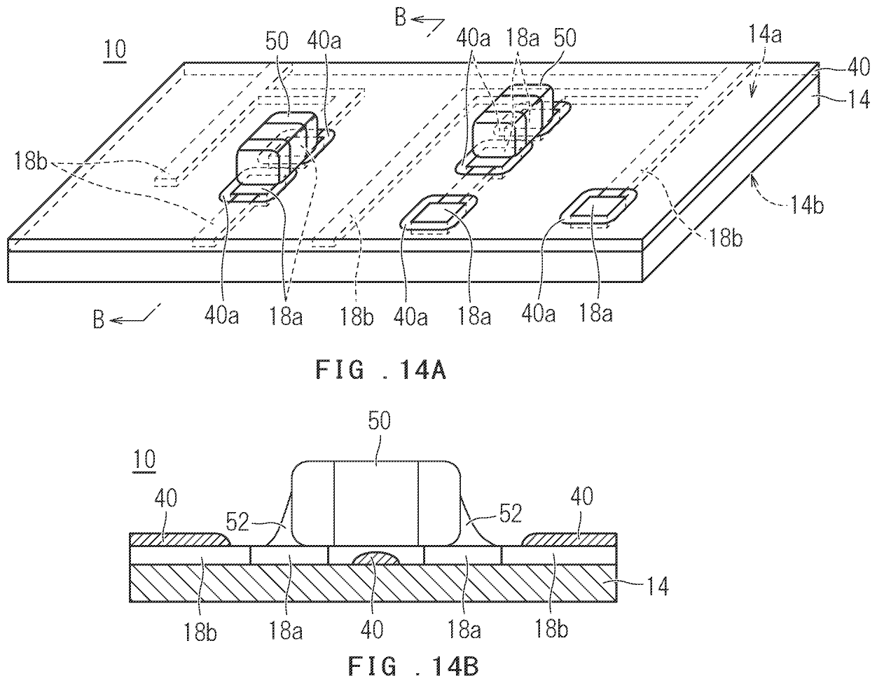

FIG. 14(A) is a diagram illustrating a schematic structure in which electronic components are mounted on the printed wiring board according to an example formed by the method of manufacturing a printed wiring board according to the embodiment of the present invention. Further, FIG. 14(B) is a cross-sectional view taken along line B-B in FIG. 14(A). As illustrated in FIG. 14(A), the wiring pattern portion 18b other than the land portion is covered with the solder resist layer 40. Further, at a periphery of the land portion 18a, an opening 40a of the solder resist layer is provided for mounting the electronic component 50 or the like. As illustrated in FIG. 14(B), the external electrode or the like of the electronic component 50 and the land portion 18a are electrically connected by the bonding material 52 such as solder. Note that the solder resist layer 40 may be provided between the land portion 18a and an adjacent one of the land portions 18a.

### 2. Manufacturing Method of Printed Wiring Board

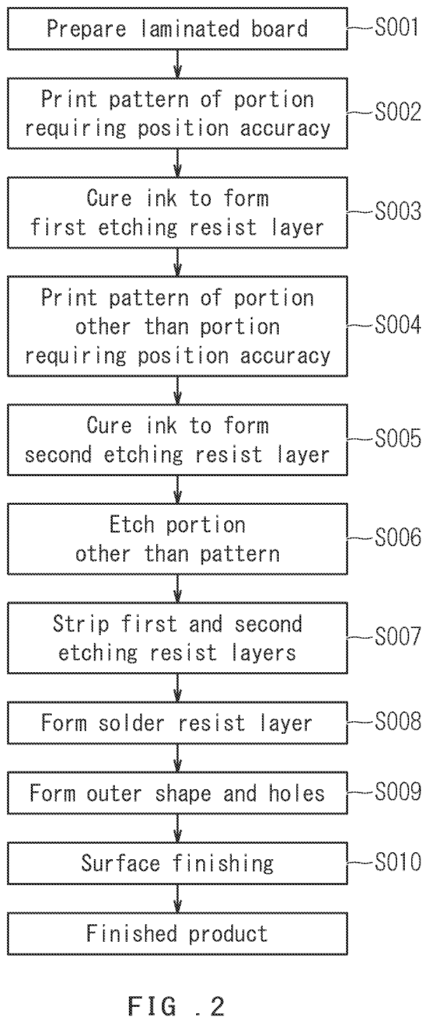

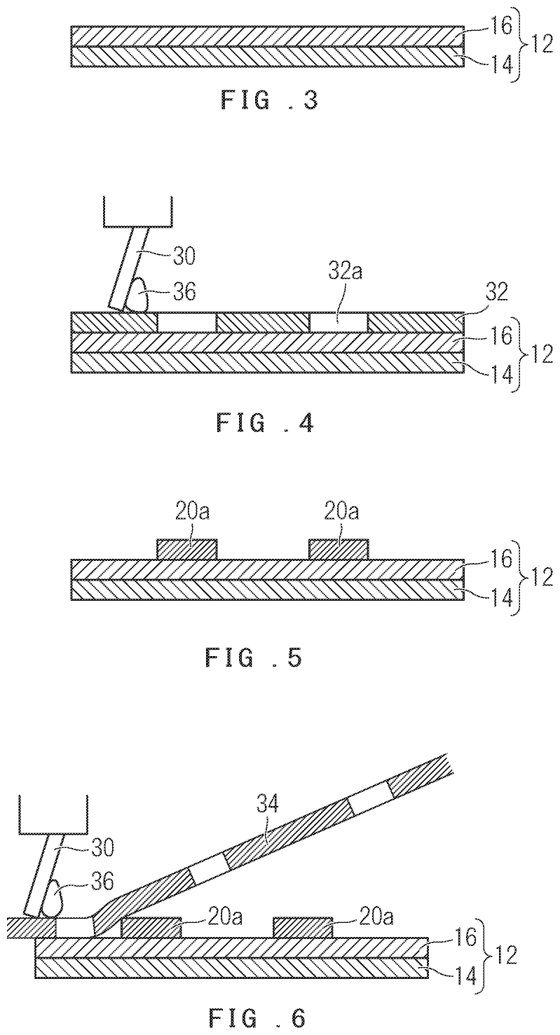

FIG. 2 is a flowchart illustrating a method of manufacturing a printed wiring board according to the embodiment of the present invention. Further, FIGS. 3 to 9 are cross-sectional views illustrating cross sections of the printed wiring board in each step in the flowchart illustrating the manufacturing method of FIG. 2. Note that FIGS. 3 to 9 are cross-sectional views of locations corresponding to line A-A of FIG. 1 in each step.

First, a laminated board 12 in which the metal layer 16 is formed on the front surface of the base material 14 is prepared (step S001). FIG. 3 illustrates a cross section of the laminated board 12 prepared in step S001.

Next, a metal mask 32 is used to print a pattern of the land portions 18a, being portions requiring position accuracy (step S002). FIG. 4 illustrates a state where printing with an etching resist ink 36 for forming a first etching resist layer 20a at positions of the land portions 18a is performed in step S002.

As illustrated in FIG. 4, the metal mask 32 is placed on a surface of the laminated board 12, and printing with the etching resist ink 36 is performed while pressing a squeegee 30 against the metal mask 32 in parallel with the laminated board 12. After that, the metal mask 32 is removed from the laminated board 12.

Next, the etching resist ink 36 printed on the surface of the laminated board 12 is cured to form the first etching resist layer 20a (step S003). FIG. 5 illustrates a state where the etching resist ink 36 is cured in step S003. The first etching resist layer 20a is formed as a result of steps S002 and S003.

Here, the metal mask 32 is, for example, a metal plate made of stainless steel. Unlike a screen plate, the metal mask 32 is placed on the surface of the laminated board 12 when performing printing, and thus highly accurate printing can be performed.

Further, the thickness of the metal plate forming the metal mask 32 is preferably 0.02 mm or more. If a metal plate having a thickness of 0.02 mm or more is chosen, it is possible to prevent the metal mask 32 from being deformed due to the printing pressure of the squeegee or the like.

Further, portions of the metal mask 32 corresponding to the land portions 18a are formed so as to penetrate the metal plate. Based on the pattern 18, through holes 32a are formed at the portions corresponding to the land portions 18a, by, for example, laser processing, etching processing, or additive processing. Laser processing is a method of producing the through holes 32a by a laser processing machine. Therefore, the through holes 32a can be formed with high accuracy. Further, the etching processing is a method of forming the through holes 32a by chemical etching. Therefore, a number of holes can be formed simultaneously. The additive processing is a method of forming the through holes 32a by electroforming using nickel (Ni). Therefore, it is possible to produce the fine through holes 32a.

Moreover, in addition to the above-mentioned types of processing, electrolytic polishing, fluorine coating, half-etching and the like may be employed. In electrolytic polishing, the unevenness of an inner wall of the through holes 32a can be smoothed by passing a direct current between the metal mask 32 serving as an anode and a cathode serving as a counter electrode, via an electrolytic solution. Further, in the fluorine coating, the unevenness of the inner wall of the through holes 32a can be smoothed by applying a fluororesin to the inner wall of the through holes 32a. Moreover, in the half-etching, when it is desired to adjust the amount of ink in a specific one of the through holes 32a, the through holes 32a can be formed with a different plate thickness in one metal mask. The through holes 32a formed by using laser processing, etching processing, additive processing, or the like are further subjected to processing such as electrolytic polishing, fluorine coating, and half-etching to make the through holes 32a smoother. In particular, it is preferable to perform the electrolytic polishing and/or fluorine coating after the laser processing. If the electrolytic polishing and/or fluorine coating are performed in addition to the laser processing, it is possible to further smoothen the unevenness of the inner wall of the through holes 32a. Consequently, the first etching resist layer 20a can be formed with higher accuracy.

Further, for example, it is possible to use, as the metal mask 32, a directly attached metal mask in which a metal plate is directly bonded to a frame, or a combination mask fabricated by bonding a mesh made of such as polyester or stainless steel to a frame and bonding a metal plate within the mesh. In particular, if the combination mask is used, the metal mask 32 can be produced at a lower cost than the directly attached metal mask.

Further, when performing printing with the etching resist ink 36 to form the first etching resist layer 20a, it is preferable to use the squeegee 30 having a type A durometer hardness defined in JIS K6253-3 of 60 or more. If the squeegee 30 described above is used, the etching resist ink 36 can be applied to the surface of the metal mask 32 with an appropriate pressure, and printing with the etching resist ink 36 can be performed smoothly. Various materials such as metal, plastic, and urethane can be used as the material of the squeegee 30. Further, it is desirable that the printing pressure of the squeegee 30 is as low as possible.

Next, a screen plate 34 is used to print the wiring pattern portion 18b, being a portion other than the portion requiring position accuracy (step S004). FIG. 6 illustrates a state where printing with the etching resist ink 36 for forming a second etching resist layer 20b at positions of the wiring pattern portions 18b other than the land portions is performed in step S004.

As illustrated in FIG. 6, the screen plate 34 is placed on the first etching resist layer 20a, and printing with the etching resist ink 36 is performed while pressing the squeegee 30 against the screen plate 34 in parallel with the laminated board 12. After that, the screen plate 34 is removed from the laminated board 12.

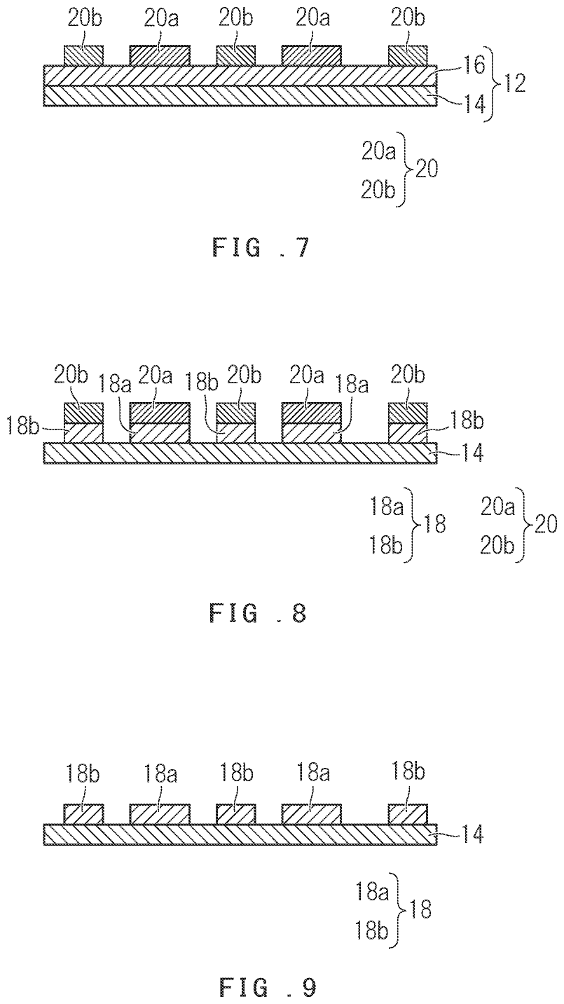

Next, the etching resist ink 36 printed on the surface of the laminated board 12 is cured to form the second etching resist layer 20b (step S005). FIG. 7 illustrates a state after printing with the etching resist ink 36 for forming the second etching resist layer 20b at positions of the wiring pattern portions 18b is performed in step S004. The second etching resist layer 20b is formed as a result of steps S004 and S005.

Here, the screen plate 34 is, for example, a mesh made of stainless steel, polyester, or polyarylate, and the like, and only the wiring pattern portion 18b other than the land portion is opened. When printing with the screen plate 34 is performed, a gap (clearance) is provided between the screen plate 34 and the laminated board 12, and printing is performed on the laminated board 12 while pulling the screen plate 34.

Note that the etching resist ink 36 used when forming the first etching resist layer 20a and the second etching resist layer 20b is preferably a UV-curable ink. When the UV-curable ink is used as the etching resist ink 36, the etching resist ink 36 is cured by irradiation with ultraviolet rays. If the UV-curable ink is used, the heat for curing the etching resist ink is low, and thus, it is possible to form the first etching resist layer 20a and the second etching resist layer 20b in a state where the base material 14 contracts little.

Further, it is desirable that the etching resist ink 36 has a viscosity at which printing by the metal mask 32 and the screen plate 34 is possible.

Next, the metal layer 16 of the laminated board 12 is etched to remove a portion other than the pattern 18 (step S006). FIG. 8 illustrates a state where a portion other than the pattern 18 is etched in step S006.

Subsequently, the first etching resist layer 20a and the second etching resist layer 20b are stripped by an ink stripping agent, to remove the first etching resist layer 20a and the second etching resist layer 20b (step S007). FIG. 9 illustrates a state where the first etching resist layer 20a and the second etching resist layer 20b are stripped in step S007.

Next, the solder resist layer 40 is formed by performing, on a portion of the pattern not to be soldered, solder resist printing using a solder resist ink, and then, curing the solder resist ink (step S008).

Finally, a process for forming an outer shape and holes (step S009), and a process for finishing the surface (step S010) are performed. In the process of finishing the surface, acid is used to degrease and rust-proof the surface, with the purpose of cleaning the surface of the portion of the pattern where the solder resist layer is not formed. As a result, the printed wiring board 10 in which the pattern 18 is formed on the base material 14 is manufactured.

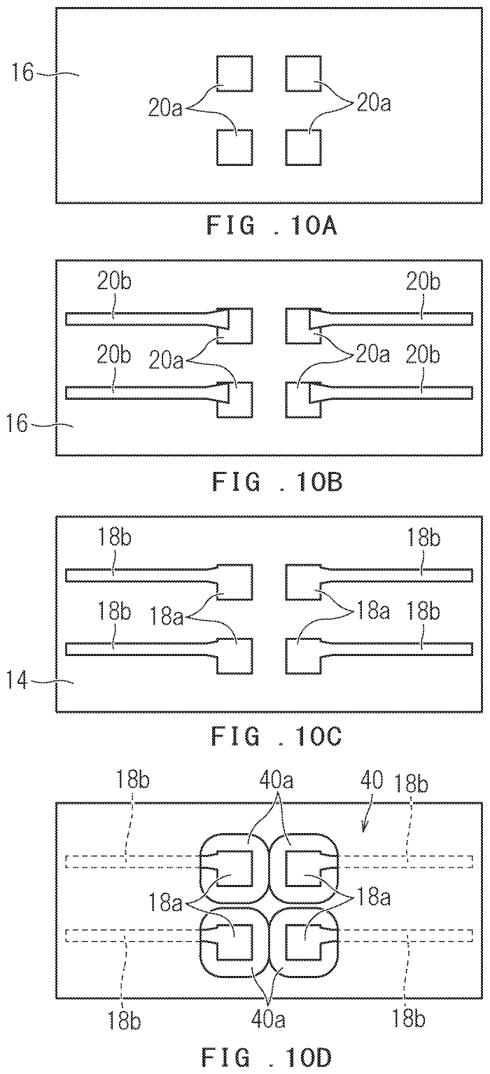

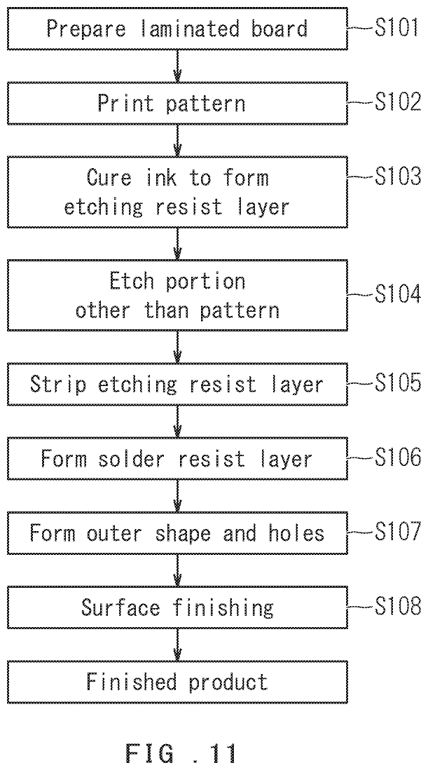

FIG. 10 is a plan view of a printed wiring board fabricated in the manufacturing process of FIG. 2, when viewed from above.

FIG. 10(A) is a plan view of the laminated board 12 after step S003 is completed, when viewed from above. The first etching resist layer 20a is formed on the metal layer 16 of the laminated board 12.

FIG. 10(B) is a plan view of the laminated board 12 after step S005 is completed, when viewed from above. The second etching resist layer 20b is formed on the metal layer 16 of the laminated board 12 so as to partially overlap the first etching resist layer 20a. FIG. 10(C) is a plan view of the printed wiring board 10 after step S007 is completed, when viewed from above. A portion other than the portions where the first etching resist layer 20a and the second etching resist layer 20b are formed is etched and the first etching resist layer 20a and the second etching resist layer 20b are stripped. As a result, the pattern 18 including the land portions 18a and the wiring pattern portions 18b other than the land portions, is formed.

FIG. 10(D) is a plan view of the laminated board 12 after step S008 is completed, when viewed from above. The solder resist layer 40 is formed so as to cover a part of the wiring pattern portion 18b other than the land portion. The opening 40a of the solder resist layer is provided for the land portion 18a and for a part of the wiring pattern portion 18b other than the land portion in a periphery of the land portion 18a. This makes it possible to mount the electronic component 50.

### 3. Experimental Example

The following experiment was conducted to compare a positional deviation in a case where the metal mask 32 is used for printing and in a case where the screen plate 34 is used for printing.

In the experiment, a printed wiring board fabricated according to the manufacturing process of the present invention illustrated in FIG. 2 was compared with a printed wiring board fabricated according to the conventional manufacturing process illustrated in FIG. 11.

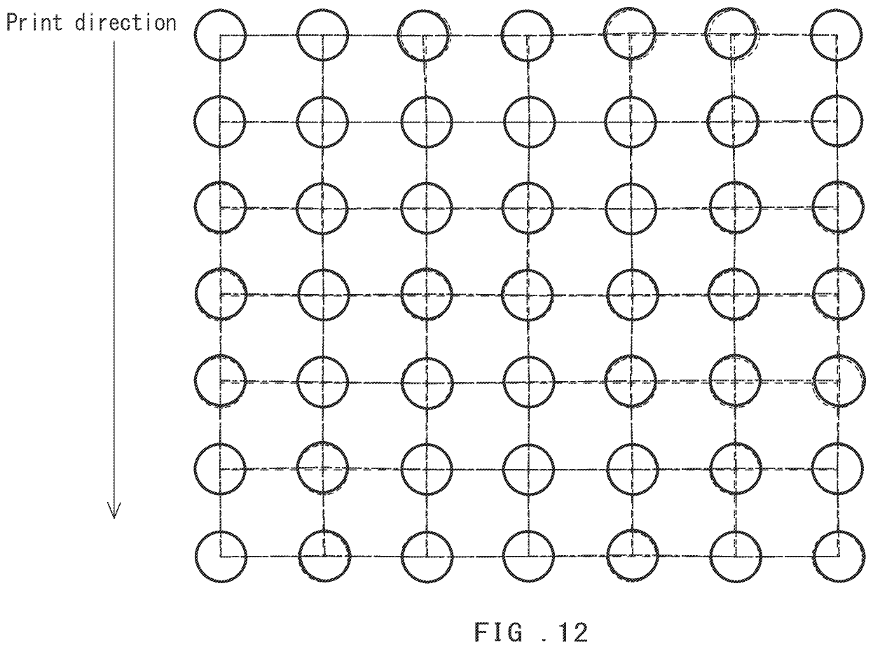

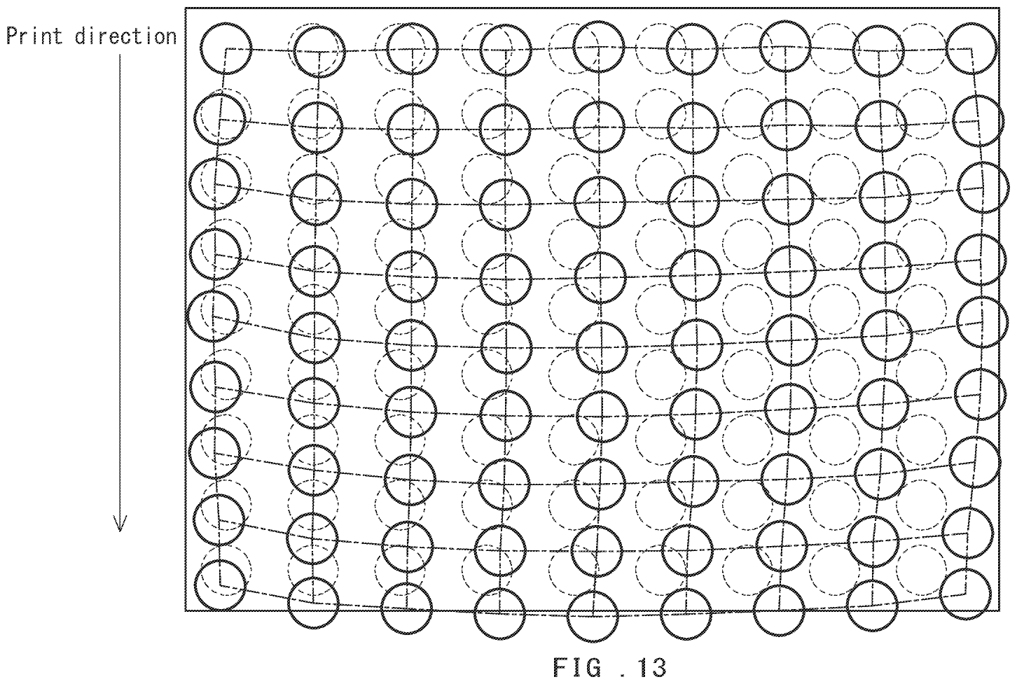

FIG. 12 is a diagram illustrating a positional deviation of the etching resist layer in a case where the metal mask 32 is used for printing. FIG. 13 is a diagram illustrating a positional deviation of the etching resist layer in a case where the screen plate 34 is used for printing. In FIGS. 12 and 13, design positions are illustrated by a dashed line and measured positions are illustrated by a solid line. In addition, lines connecting the centers of the measured positions are indicated by an alternate long and short dash line.

As illustrated in FIGS. 12 and 13, it can be seen that the positional deviation from the design positions is significantly reduced in the case where the metal mask 32 is used. The maximum deviation in the case where the metal mask 32 is used was 18 μm. On the other hand, in the case where the screen plate 34 is used, the maximum deviation was 150 μm or more. Further, in the case where the metal mask 32 is used, an etching resist layer without distortion is formed.

In the above embodiment, a case where the portion requiring position accuracy is the land portion for mounting the electronic component has been described, but the present invention is not limited thereto.

For example, when an electronic component is automatically inserted to and/or automatically mounted on the printed wiring board 10, a fiducial mark may be provided on the surface of the printed wiring board 10, as a mark for aligning the printed wiring board 10 with an inserting machine or a mounter. In this case, the fiducial mark is a portion requiring position accuracy, as with the land portion. Therefore, a pattern of the fiducial mark may be printed in step (S002) in which the metal mask 32 is used to print the pattern of the portion requiring position accuracy.

Further, in the embodiment described above, a case where the etching resist ink 36 is a UV-curable ink has been described, but the present invention is not limited thereto. For example, a thermosetting ink may be used as the etching resist ink 36.

As described above, in a printing process using a conventional screen plate, printing with the etching resist ink is performed on the metal layer of the laminated board while pulling the screen plate 34, and thus, a positional deviation often occurs in the etching resist layer. However, in the present invention, the metal mask 32 is used to print a pattern of the portion 18a where position accuracy is required (for example, a land portion or a fiducial mark portion), to form the first etching resist layer 20a, and thus, the portion 18a where position accuracy is required can be accurately formed at a predetermined position. Further, in the present invention, the screen plate 34 is used to print a pattern of the portion 18b other than the portion requiring position accuracy (for example, a wiring pattern portion other than the land portion, or a portion other than the fiducial mark portion), to form the second etching resist layer 20b. Subsequently, portions of the metal layer 16 other than the first etching resist layer 20a and the second etching resist layer 20b are simultaneously removed by etching, and the first etching resist layer 20a and the second etching resist layer 20b are simultaneously stripped. Thus, it is possible to realize a method of manufacturing a printed wiring board that allows for improving overall mass productivity and achieving cost reduction.

Note that, in order to print the pattern 18 with high accuracy, a method in which all the patterns are printed by using the metal mask 32 may also be considered. However, when the patterns 18 are close to each other, the strength of the metal mask 32 decreases and the metal mask 32 may deform during printing. Therefore, it is preferable to use the metal mask 32 and the screen plate 34 together, as in the present invention.

As described above, embodiments of the present invention are disclosed in the above description, but the present invention is not limited thereto.

That is, various modifications can be made to the above-described embodiments with respect to the mechanism, shape, material, number of components, positions, arrangement, and the like, without departing from the technical idea and purpose of the present invention, and these modifications are included in the present invention.

### REFERENCE SIGNS LIST

10 Printed wiring board
12 laminated board
14 Base material
16 Metal layer
18 Pattern
18a Land portion (portion requiring position accuracy)
18b Wiring pattern portion other than land portion (portion other than portion requiring position accuracy)
20 Etching resist layer
20a First etching resist layer (land portion)
20b Second etching resist layer (wiring pattern portion other than land portion)
30 Squeegee
32 Metal mask
32a Through hole
34 Screen plate
36 Etching resist ink (UV-curable ink)
40 Solder resist layer
40a Opening of solder resist layer
50 Electronic component
52 Bonding material (solder)

1. A method of manufacturing a printed wiring board with a pattern formed using a printing process, the method comprising:
preparing a laminated board including a metal layer formed on a surface of a base material;
forming a first etching resist layer by printing a pattern of a portion requiring position accuracy on the metal layer of the laminated board using a metal mask;
forming a second etching resist layer by printing a pattern of a portion other than the portion requiring position accuracy on the metal layer of the laminated board using a screen plate;
removing, by etching, the metal layer of the laminated board where the first etching resist layer and the second etching resist layer are not formed; and
stripping the first etching resist layer and the second etching resist layer.

2. The method of manufacturing a printed wiring board according to claim 1, wherein the portion requiring position accuracy includes a land portion for mounting an electronic component.

3. The method of manufacturing a printed wiring board according to claim 1, wherein the portion requiring position accuracy includes a fiducial mark portion for positioning the printed wiring board.

4. The method of manufacturing a printed wiring board according to claim 1, wherein a thickness of the metal mask is 0.02 mm or more.

5. The method of manufacturing a printed wiring board according to claim 1, wherein the metal mask is a combination mask.

6. The method of manufacturing a printed wiring board according to claim 1, wherein a UV-curable ink is used to print a pattern in the forming the first etching resist layer and the forming the second etching resist layer.

7. The method of manufacturing a printed wiring board according to claim 1, wherein a squeegee having a type A durometer hardness defined in JIS K6253-3 of 60 or more is used when printing the pattern by using the metal mask in the forming the first etching resist layer.
